(19) United States
(12) Patent Application Publication
(10) Pub. No.: US 2026/0291483 A1
(43) Pub. Date: Sep. 24, 2026

(54) HIGH EFFICIENCY LOW-POWER ACTIVE CABLE ARCHITECTURE

(71) Applicant: Lerain Technology Co., Ltd., New Taipei City (TW)

(72) Inventors: CHE-YING LI, New Taipei City (TW); WEN-SHENG YANG, New Taipei City (TW); HSIN-CHE CHIANG, New Taipei City (TW); LI-AN HO, New Taipei City (TW); MIAOBIN GAO, New Taipei City (TW)

(21) Appl. No.: 19/252,744

(22) Filed: Jun. 27, 2025

(30) Foreign Application Priority Data
Mar. 19, 2025 (TW) 114110366

(51) Int. Cl. H03K 17/0412; H04B 3/54

(52) U.S. Cl. CPC H03K 17/04123; H04B 3/54

(57) ABSTRACT

A high efficiency low-power active cable architecture is disclosed. The high efficiency low-power active cable architecture can connect between a first and a second electronic device, comprising first and second connection ports, a power line, a transmission line, a diode, a switch module, a first and a second control circuits. The power line and transmission line can connect to the first or second electronic device to receive a power signal and a transmitted signal. The diode, the switch module, and the control circuit are disposed inside the first connection port. The second control circuit is disposed inside the second connection port. When the first electronic device is single-ended powered, the second control circuit detects that the second electronic device has no input power signal and thereby notifies the first control circuit to control the conduction of the switch module.

### BACKGROUND OF THE INVENTION

### 1. Field of the Invention

The present invention relates to a high efficiency low-power active transmission cable architecture, particularly to an active transmission cable architecture that can effectively reduce power consumption and improve performance under single-ended power supply.

### 2. Description of the Related Art

With the advancement of technology, the transmission data rate speed of communication transmission cables is also increasing, such as USB4 V2, DP80, TBT5, and PCIe Gen6/7 specifications or models of communication transmission cables, etc. Under the consideration of active transmission cable compatibility, it is hoped that active transmission cables can be used in both single-ended and double-ended power supply applications. However, the two ends of the active transmission cable connected to two devices may have different power supply voltage levels, causing a potential difference. When the active transmission cable directly connects two electronic devices, it may cause a short circuit, thereby burning the devices. Therefore, a diode is installed into the internal circuit of the active transmission cable in the prior art.

Please refer to FIG. 1, which is a schematic diagram of the transmission cable architecture of the prior art.

In the prior art, the transmission cable architecture 90 utilizes a first connection port 91, a second connection port 92, and a power line 94 to connect between different electronic devices. The first connection port 91 contains a first diode 931, and the second connection port 92 contains a second diode 932. The first diode 931 and the second diode 932 are located on the transmission path of the power signal. These first diode 931 and second diode 932 are to prevent the power of the remote device and the near device directly connecting to the transmission cable architecture 90, causing a short circuit of the device. However, in the active transmission cable 90 of the prior art, under the single-ended power supply condition, when the near device connected to the first connection port 91 is powered, the first diode 931 of the first connection port 91 will always have a forward bias. This forward bias, if not eliminated, will cause a power loss. The first diode 931 will always generate the power dissipation, even leading to heat generation. If the power supply in the single-end configuration is switched to the remote device connected to the second connection port 92, the second diode 932 will also experience the same power loss. Thus, the active transmission cable 90 under single-ended power supply conditions will consume a significant amount of power dissipation, causing energy waste.

Therefore, it is necessary to invent a new high efficiency active transmission cable architecture that can reduce power consumption to address the deficiencies of prior art.

### SUMMARY OF THE INVENTION

The main objective of the present invention is to provide a high efficiency low-power active transmission cable architecture capable of effectively reducing unwanted power consumption under single-ended power supply conditions to enhance performance.

To achieve the aforementioned objectives, the high efficiency low-power active transmission cable architecture of the present invention can be connected between the first electronic device and the second electronic device, wherein both the first electronic device and the second electronic device can input power signals. The high efficiency low-power active transmission cable architecture includes a first connection port, a second connection port, a power line, and a transmission line, a first diode, a first switch module, a first control circuit, and a second control circuit. The first connection port or the second connection port can be connected to the first electronic device or the second electronic device, respectively. The power line and the transmission line are connected between the first connection port and the second connection port, and can be connected to the first electronic device or the second electronic device to receive power signals and transmission signals. The first diode is disposed inside the first connection port and electrically connected to the power line. The first switch module is disposed inside the first connection port and bridged across the first diode. The first control circuit is disposed inside the first connection port to electrically connect the first switch module; the second control circuit is disposed inside the second connection port and electrically connects to the first control circuit via the transmission line. When the first electronic device is single-ended powered, the second control circuit detects that the second electronic device has no input power signal and thereby notifies the first control circuit to generate a first control signal to control the conduction of the first switch module via the transmission line, thereby eliminating the power consumption of the first diode.

In one embodiment of the high efficiency low-power active transmission cable architecture of the present invention, further includes a second diode and a second switch module. The second diode is disposed in the second connection port and electrically connected to the power line. The second switch module is disposed in the second connection port and bridged across over the second diode. When the second electronic device is single-ended powered, the first control circuit detects that the first electronic device has no input power signal and thereby notifies the second control circuit to generate a second control signal to control the conduction of the second switch module via the transmission line; thereby eliminating the power consumption of the second diode.

In one embodiment of the high efficiency low-power active transmission cable architecture of the present invention, the first switch module and the second switch module are metal oxide semiconductor field effect transistors.

In one embodiment of the high efficiency low-power active transmission cable architecture of the present invention, wherein the power line and the transmission line are covered by the same insulation jacket.

### BRIEF DESCRIPTION OF THE DRAWINGS

All the objects and advantages of the present invention will become apparent from the following description of the accompanying drawings, which disclose several embodiments of the present invention. It should be understood that the drawings are used for purposes of illustration only, and not as a definition of the invention.

FIG. 1 is a schematic diagram of the transmission cable architecture connected structure of the prior art.

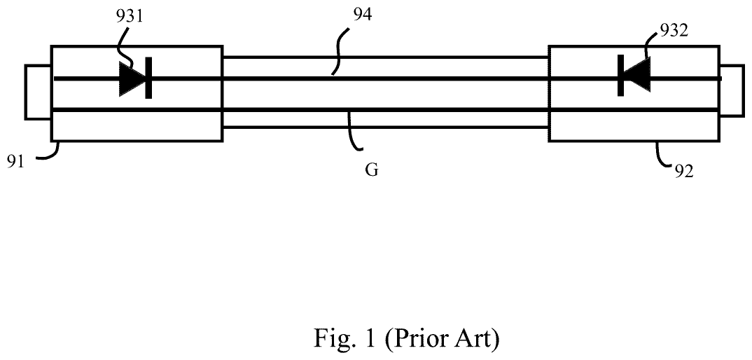

FIG. 2 is a schematic diagram of the high efficiency low-power active transmission cable architecture of the present invention.

### DETAILED DESCRIPTION OF THE PREFERRED EMBODIMENTS

Preferred specific embodiments are given below for better understanding of the technical contents of the present invention.

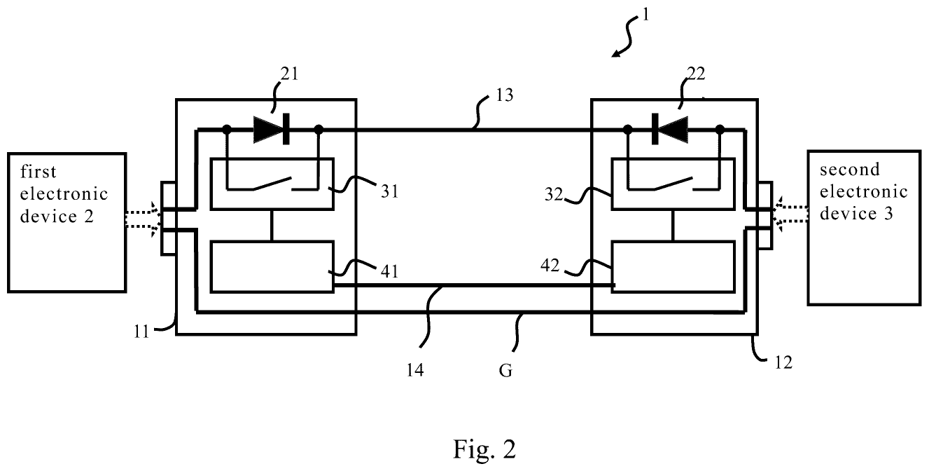

Please refer to FIG. 2, which is a schematic diagram of the high efficiency low-power active transmission cable architecture of the present invention.

In one embodiment of the present invention, the high efficiency low-power active transmission cable architecture 1 utilizes the first connection port 11 and the second connection port 12 to connect between a first electronic device 2 and a second electronic device 3. The high efficiency low-power active transmission cable architecture 1 can be applicable for bidirectional transmission or unidirectional transmission. The first electronic device 2 and the second electronic device 3 can respectively be desktop computer systems, laptops, smartphones, tablets, wearable devices, or displays, etc. The first electronic device 2 can be set as a primary control and signal output host, while the second electronic device 3 can be set as a device to be connected and receive signals. However, the present invention is not limited to this. In one embodiment of the present invention, the signal is transmitted from the first connection port 11 to the second connection port 12 as forward transmission, and the signal is transmitted from the second connection port 12 to the first connection port 11 as reverse transmission. The first connection port 11 can be set as the near-end port, and the second connection port 12 can be set as the far-end port. However, forward or reverse transmission, near-end or far-end port are merely set in the description, and the present invention is not limited to these names. Since the connection method of the high efficiency low-power active transmission cable architecture 1 has been familiar to those skilled in the art of the present invention, it is not repeated here.

In one embodiment of the present invention, the high efficiency low-power active transmission cable architecture 1 includes a first connection port 11, a second connection port 12, a power line 13, a transmission line 14, a first diode 21, a first switch module 31, a first control circuit 41, and a second control circuit 42. The first connection port 11 and the second connection port 12 are connected via the power line 13, and the power line 13 is connected to the first electronic device 2 and the second electronic device 3. The power line 13 can be isolated from the power signals provided by the first electronic device 2 or the second electronic device 3 using the first diode 21 and the second diode 22. The first connection port 11 and the second connection port 12 also have a transmission line 14 and a ground line G or an additional line for data transmission (not shown). The present invention is not limited to the internal structure of the high efficiency low-power active transmission cable architecture 1 having only the number of lines as shown in FIG. 2, nor does it restrict the usage of the lines. The above-mentioned power line 13, transmission line 14, and ground line G can be covered in the same insulation jacket, but the present invention is not limited to this.

The first diode 21, the first switch module 31, and the first control circuit 41 are all disposed on the circuit board (not shown) within the first connection port 11. The first diode 21 can be connected to the first electronic device 2 via the power line 13. The first switch module 31 is bridged across the first diode 21, and the first switch module 31 is also connected to the power line 13. The first control circuit 41 is electrically connected to the first switch module 31, and both the first control circuit 41 and the second control circuit 42 can detect whether the power signals are input, for example, by measuring the voltage change of the internal resistance component (not shown). However, the present invention is not limited to this detection method. When the first electronic device 2 is single-ended powered, the power line 13 will transmit the power signals input from the first electronic device 2 to the first, second control circuits 41, 42 via the internal circuit. At this time, the second control circuit 42 can detect that the second electronic device 3 does not input power signals, so it will notify the first control circuit 41 to generate a first control signal via the transmission line 14 to control the conduction of the first switch module 31. Thus, the power signals will be conducted to the second connection port 12 via the path of the first switch module 31, thereby reducing the wasted power caused by the forward bias of the first diode 21, improving the power efficiency, and also reducing the heat energy generated by the first diode 21, preventing the temperature of the first diode 21 from rising too high.

In one embodiment of the present invention, the high efficiency low-power active transmission cable architecture 1 also has a second diode 22 and a second switch module 32. The second diode 22, second switch module 32, and second control circuit 42 are all disposed on the circuit board (not shown) within the second connection port 12. The second diode 22 is also connected to the second electronic device 3 via the power line 13. The second switch module 32 is bridged across to the second diode 22, and the second switch module 32 is also connected to the power line 13. The second control circuit 42 is electrically connected to the second switch module 32. When the second electronic device 3 is single-ended powered, the power line 13 will transmit the power signal input from the second electronic device 3 to the first and second control circuits 41, 42 via the internal circuit. As a result, the first control circuit 41 can detect that the first electronic device 2 does not have the input power signal, so it will notify the second control circuit 42 to generate a second control signal via the transmission line 14 to control the conduction of the second switch module 32. Accordingly, the power signal will be conducted via the path of the second switch module 32 to the second connection port 12, thereby eliminating the power dissipation caused by the forward bias of the second diode 22, enhancing electrical efficiency, and also reducing the heat energy generated by the second diode 22, preventing the temperature of the second diode 22 from rising too high.

In one embodiment of the present invention, the functions of the above-mentioned first switch module first switch module 31 and the second switch module 32 are actually the same, and both can be metal oxide semiconductor field effect transistors (MOSFETs). Therefore, the first control circuit first control circuit 41 and the second control circuit second control circuit 42 are respectively electrically connected to the gates of the first switch module 31 and the second switch module 32 to control the conduction of the first switch module 31 and the second switch module 32. Under this condition, taking the conduction of the first switch module 31 as an example, if the current flowing through the first diode first diode 21 is 0.5 A, the forward bias voltage of the first diode first diode 21 is 0.3V, the power consumption of the first diode first diode 21 is 0.15 W. Conversely, the resistance of the first switch module 31 during conduction is 0.06 Ohm, with the same current, the power consumption of the first switch module 31 is 0.015 W. Therefore, the power consumption of the first switch module 31 will be much lower than the power consumption of the original first diode 21 caused by forward bias. Similarly, the power consumption of the second switch module 32 will also be much lower than the power consumption of the original second diode 22 caused by forward bias.

From the above description, it is known that the configuration of the first switch module 31 or the second switch module 32 of the high efficiency low-power active transmission cable architecture 1 of the present invention can effectively solve the problem of virtual power consumption caused by forward bias of the first diode 21 or the second diode 22. Ultimately, it can prevent the temperature of the transmission cable architecture 1 from becoming too high.

It is noted that the above-mentioned embodiments are only for illustration. It is intended that the present invention covers modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A high efficiency low-power active transmission cable architecture for connecting between a first electronic device and a second electronic device, wherein both the first electronic device and the second electronic device can input a power signal; the high efficiency low-power active transmission cable architecture comprising:
a first connector port;
a second connection port, wherein the first connection port or the second connection port can be respectively connected to the first electronic device or the second electronic device;
a power line, connected between the first connection port and the second connection port, and can be connected to the first electronic device or the second electronic device to receive the power signal;
a transmission line, connected between the first connection port and the second connection port;
a first diode, disposed inside the first connection port and electrically connected to the power line;
a first switch module, disposed inside the first connection port and bridged across the first diode;
a first control circuit, disposed inside the first connection port to electrically connect the first switch module; and
a second control circuit, disposed inside the second connection port and electrically connected to the first control circuit via the transmission line;
wherein when the first electronic device is single-ended powered, the second control circuit detects that the second electronic device has no input power signal and thereby notifies the first control circuit to generate a first control signal to control a conduction of the first switch module via the transmission line; thereby eliminating a power consumption of the first diode.

2. The high efficiency low-power active transmission cable architecture as claimed in claim 1 further comprising:
a second diode disposed within the second connection port and electrically connected to the power line; and
a second switch module disposed within the second connection port and bridged across the second diode; wherein when the second electronic device is single-ended powered, the first control circuit detects that the first electronic device has no input power signal, and thereby notifies the second control circuit to generate a second control signal to control a conduction of the second switch module via the transmission line; thereby eliminating a power consumption of the second diode.

3. The high efficiency low-power active transmission cable architecture as claimed in claim 2, wherein the first switch module and the second switch module are both metal oxide semiconductor field-effect transistors.

4. The high efficiency low-power active transmission cable architecture as claimed in claim 2, wherein the power line and the transmission line are covered within the same insulation jacket.
